(19) United States
(12) Patent Application Publication
(10) Pub. No.: US 2025/0104747 A1
(43) Pub. Date: Mar. 27, 2025

(54) NON-VOLATILE MEMORY ARCHITECTURE

(71) Applicant: STMicroelectronics International N.V., Geneva (CH)

(72) Inventors: Alin RAZAFINDRAIBE, Saint Martin d'Heres (FR); Thomas JOUANNEAU, St-Egreve (FR); Xavier LECOQ, Voiron (FR)

(73) Assignee: STMicroelectronics International N.V., Geneva (CH)

(21) Appl. No.: 18/886,002

(22) Filed: Sep. 16, 2024

(30) Foreign Application Priority Data
Sep. 22, 2023 (FR) 2310039

(51) Int. Cl. G11C 7/10; G11C 11/54

(52) U.S. Cl. CPC G11C 7/1096; G11C 7/1069; G11C 11/54

(57) ABSTRACT

A non-volatile memory includes a first area with first storage elements configured to store values associated with first neurons of a network and a second area with second storage elements. A control circuit applies one or more first input values to first read paths, each first read path including one among the first storage elements. A computing circuit adds currents supplied by the first read paths to generate an output current. A programming circuit converts the output current into a programming current, and uses the programming current to program a second storage element.

### PRIORITY CLAIM

This application claims the priority benefit of French Application for Patent No. 2310039, filed on Sep. 22, 2023, the content of which is hereby incorporated by reference in its entirety to the maximum extent allowable by law.

### TECHNICAL FIELD

The present disclosure generally concerns non-volatile memories configured to perform computing operations. In particular, the present disclosure concerns a non-volatile memory configured to perform computing operations between a plurality of layers of an artificial neural network.

### BACKGROUND

The functioning of neural networks generally implies the execution, by a processor, of advanced algorithms. The computing operations, such as convolutions and/or matrix computing operations, controlled during the execution of the algorithms then imply data transfers between a non-volatile and/or volatile memory and the processor. The transferred data are, for example, parameters of the neural network, such as weights. The intermediate results between successive computing operations are, for example, temporarily stored in a volatile memory.

Each data transfer between the non-volatile memory and/or the volatile memory and the processor is time and power intensive. This results, for example, in delay times in the data processing by the neural network, as well as in a decreased data processing performance.

There exists a need to improve the execution of computing operations controlled during the data processing by an artificial neural network.

### SUMMARY

An embodiment provides a non-volatile memory comprising: a first memory area comprising a first plurality of storage elements, configured to store values of weights associated with a first plurality of neurons of a neural network; a second memory area comprising a second plurality of storage elements; a control circuit, configured to apply, to a plurality of first read paths, one or more first input values, each first read path comprising one among the storage elements of the first plurality of storage elements; a first computing circuit configured to add currents supplied by the first read paths to generate a first output current; and a programming circuit configured to convert the first output current into a first programming current, and to program a first storage element of the second plurality of storage elements by using said first programming current.

According to an embodiment, the one or more first input values are applied simultaneously to the plurality of first read paths.

According to an embodiment, the control circuit is further configured to apply, to a plurality of second read paths, one or more second input values generated by reading the first one of the second plurality of storage elements, each second read path comprising one among the storage elements of the first plurality of storage elements, the non-volatile memory further comprising: a second computing circuit, configured to add currents supplied by the second read paths to generate a second output current, the programming circuit being configured to convert the second output current into a second programming current, and to program another storage element of the first area of the memory by using said second programming current.

According to an embodiment, the control circuit is further configured to apply, to a plurality of third read paths, one or more third input values generated by reading the other storage element of the first memory area, each third read path comprising one among the storage elements of the first plurality of storage elements, and the first computing circuit is further configured to add currents supplied by the third read paths to generate a third output current, the programming circuit being further configured to convert the third output current into a third programming current, and to reprogram the first storage element of the second plurality of storage elements by using said third programming current.

According to an embodiment, the storage elements comprised in the first read paths define the weights associated with an input layer of the neural network and the storage elements comprised in the third read paths define the weights associated with another layer, or with an output layer, of the neural network.

According to an embodiment, the weights stored by the first plurality of storage elements define weights of neurons belonging to layers of odd parity, respectively of even parity, of the neural network and the weights stored by the second plurality of storage elements define weights of neurons belonging to layers of even parity, respectively of odd parity, of the neural network.

According to an embodiment, each storage element, among the first and the second plurality of storage elements, belongs to a memory cell, each memory cell being coupled to the control circuit via a word line and a bit line, the control circuit being configured to activate or deactivate word lines and bit lines.

According to an embodiment, the first computing circuit is configured to generate the first output value, based on the currents supplied by the memory cells comprised in a read path among the first read paths.

According to an embodiment, the computing circuit is further configured to apply compensation and/or threshold and/or offset and/or scaling effects, based on the currents supplied by the memory cells comprised in a read path among the first read paths.

According to an embodiment, the storage elements and the other storage elements are programmable resistive elements.

According to an embodiment, the above memory further comprises a third computing circuit configured to generate another output value, based on currents supplied by one or a plurality of memory cells comprised in a read path among the first read paths and on the one or more first input values.

According to an embodiment, the first and the third computing circuits are configured to generate the output values based on one or more cells in common in the plurality of first read paths, the common cells being duplicated in at least two sub-areas in the first area.

An embodiment provides a method comprising: applying, by a control circuit to a plurality of first read paths, one or more first input values, each first read path comprising one among storage elements of a first plurality of storage elements of a first area of a non-volatile memory, the first plurality of storage elements being configured to store weight values associated with a first plurality of neurons of a neural network; adding, by a first computing circuit, currents supplied by the first read paths to generate a first output current; converting, by a programming circuit, the first output current into a first programming current, and programming, by the programming circuit, a first storage element of a second plurality of storage elements of a second area of the non-volatile memory by using said first programming current.

According to an embodiment, the above method further comprises: applying, by the control circuit to a plurality of second read paths, one or more second input values generated by reading the first one of the second plurality of storage elements, each second read path comprising one among the storage elements of the first plurality of storage elements; adding, by a second computing circuit, the currents supplied by the second read paths to generate a second output current; converting, by the programming circuit, the second output current into a second programming current, and programming, by the programming circuit, another storage element of the first area of the memory by using said second programming current.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 schematically illustrates an artificial neural network and shows an example of operations performed by the artificial neural network;

FIG. 2 is a block diagram illustrating a non-volatile memory;

FIG. 3 illustrates a portion of the non-volatile memory;

FIG. 4 is a diagram illustrating a plurality of neurons directly implemented in the non-volatile memory;

FIG. 5A illustrates computing operations performed between first and second layers of the neural network;

FIG. 5B illustrates computing operations performed between the second and a third layer of the neural network;

FIG. 6 is a block diagram illustrating another non-volatile memory;

FIG. 7A illustrates computing operations performed between the first and the second layers of the neural network; and

FIG. 7B illustrates computing operations performed between the second and the third layer of the neural network.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail. In particular, the programming of resistive elements is known and within the abilities of those skilled in the art.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “edge”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

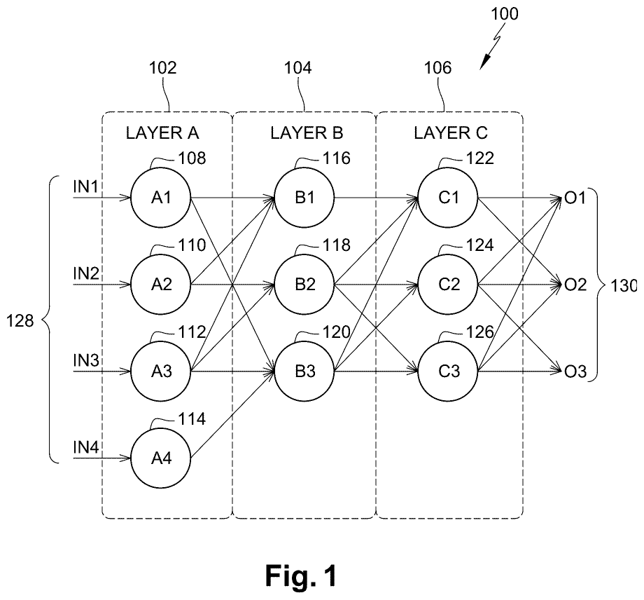

FIG. 1 schematically illustrates an artificial neural network 100 and shows an example of operations carried out by artificial neural network 100.

Artificial neural network 100 comprises, for example, a layer 102 (LAYER A), a layer 104 (LAYER B), and a layer 106 (LAYER C). As an example, layers 102 and 106 are respectively an input layer and an output layer of neural network 100. In the illustrated example, layer 102 comprises four artificial neurons 108, 110, 112, and 114 respectively associated with weights A1, A2, A3, and A4. Layer 104 comprises three artificial neurons 116, 118, and 120 respectively associated with weights B1, B2, and B3. Layer 106 comprises three neurons 122, 124, and 126 respectively associated with weights C1, C2, and C3.

As an example, an input vector 128 is supplied to layer 102 of neural network 100. Neural network 100 is then configured to generate an output vector 130 based on input vector 128. As an example, input vector 128 comprises data relative to an image, a video, or an audio tape. As an example, output vector 130 for example comprises probabilities of membership, of a target belonging to the image or to the video, to categories, etc. In another example, neural network 100 is configured to perform a voice recognition, a language processing, a speech-to-text or text-to-speech conversion, a translation, etc., based on an audio tape.

In the example illustrated in FIG. 1, input vector 128 comprises four input values IN1, IN2, IN3, and IN4. As an example, layer 102 is configured to perform a linear operation between input vector 128 and weights A1 to A4. As an example, input value IN1 is supplied to neuron 104, configured to perform multiplication A1×IN1. Similarly, each of the input values IN2, IN3, or IN4 is supplied to the corresponding neuron of weight A2, A3, or A4 and which is configured to generate the corresponding value IN′2=A2×IN2, IN′3=A3×IN3 and IN′42=A4×IN4.

As an example, neuron 108 is, for example, configured to transmit value IN′1=A1×IN1 to the neurons 116 and 120 of layer 104. As an example, neuron 116 further receives values IN′2=A2×IN2 and IN′3=A3×IN3 . Neuron 116 is, for example, configured to generate a value IN″1=B1×(IN′1+IN′2+IN′3) and, for example, to transmit it to the neuron 122 of layer 106.

In the example illustrated in FIG. 1, neuron 120 is configured to generate a value IN″3 based on the values supplied by neurons 108 and 114. As an example, value IN″3 is equal to linear combination B3×(IN′1+IN′4). Neuron 120 is, for example, further configured to supply value IN″3 to neurons 122, 124, and 126 of layer 106.

In the example illustrated in FIG. 1, neuron 122 is configured to generate an output value O1. The output value is, for example, a component of output vector 130. As an example, value O1 is equal to linear combination C1×(IN″1+IN″2+IN″3), where value IN″2 is the value generated by neuron 118, for example based on values IN′2 and IN′3 and on weights B2 and B3. Similarly, neurons 124 and 126 are respectively configured to generate output values O2 and O3, based on weights C2 and C3 and on the values IN″1 to IN″3 which are supplied thereto.

Artificial neural network 100 thus is, for example, configured to perform operations of multiply and accumulate (MAC) type.

According to an embodiment, to avoid transfer times between a non-volatile memory storing weights of the neurons, a volatile memory storing, for example, intermediate results such as values IN′1 to IN′4 and IN″1 to IN″3 and a processor configured to perform the MAC operations, the MAC operations are directly performed in the non-volatile memory (“In Memory Computing”—IMC).

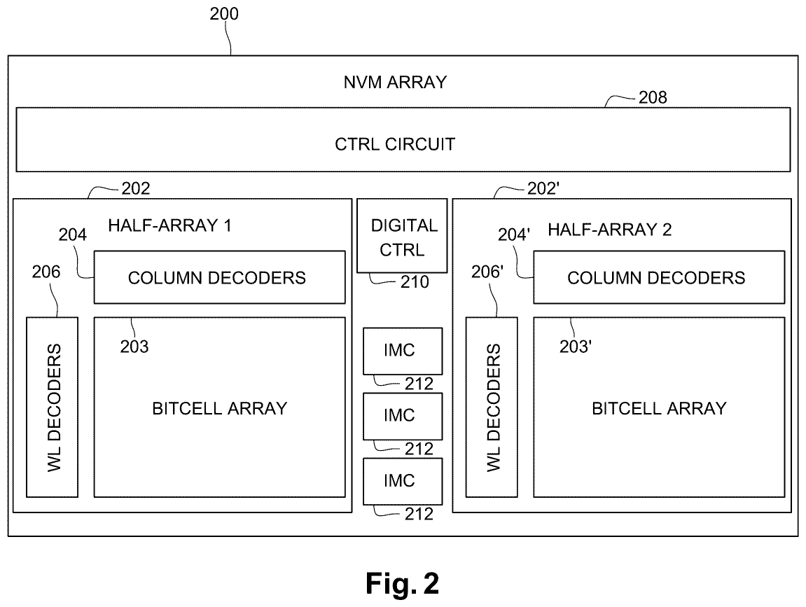

FIG. 2 is a block diagram illustrating a non-volatile memory 200. As an example, non-volatile memory 200 implements a neural network similar to neural network 100. As an example, the neural network implemented in non-volatile memory 200 is a convolutional neural network (CNN), a fully-connected neural network, etc. As an example, the neural network implemented in non-volatile memory 200 has a relatively limited size, for example comprising some ten layers.

According to an embodiment, non-volatile memory 200 comprises two memory areas 202 (HALF-ARRAY 1) and 202′ (HALF-ARRAY 2). Memory areas 202 and 202′ each comprise, for example, an array of memory cells 203 and 203′ (BITCELL ARRAY). As an example, the arrays of memory cells 203 and 203′ each comprise a plurality of memory cells, or of storage elements, addressable in rows and columns and via word lines and bit lines. Areas 202 and 202′ each comprise a column decoder 204 and 204′ (COLUMN DECODERS) and a row decoder 206 and 206′ (WL DECODERS). Each memory cell of arrays 203 and 203′ is then addressable via decoders 204 and 206, and 204′ and 206′. As an example, each memory cell implements a neuron of neural network 100.

Memory 200 further comprises a control circuit 208 (CTRL CIRCUIT) configured to control, via a digital circuit 210 (DIGITAL CTRL), decoders 204, 206, 204′, and 206′. As a result of the control by control circuit 208, decoders 204 and 206, 204′, and 206′ then activate read paths, comprising a memory cell, in array 203 or 203′. A read path corresponds, for example, to a synapse feeding a neuron, each neuron being generally fed by a plurality of synapses.

According to an embodiment, memory 200 further comprises at least one computing circuit 212 (IMC). Although FIG. 2 illustrates three circuits 212, memory 200 may of course comprise a higher or lower number of computing circuits 212. In certain cases, memory 200 comprises a plurality of computing circuits 212. Each circuit 212 is coupled to an assembly of at least one read path in array 203 and is configured to perform one or a plurality of computing operations based on the intensity of the current at the output of the read path assembly. Each computing circuit 212 is further configured to generate a value, based on the currents at the output of the read path assembly. Each computing circuit 212 is further coupled to another storage element (not illustrated in FIG. 2) comprised in area 202′ and is configured to store therein the generated value. Similarly, each circuit 212 is coupled to an assembly of at least one read path in array 203′ and is configured to perform one or a plurality of computing operations based on the intensity of the current at the output of the read path assembly.

As an example, memory 200 is placed, by control circuit 208, in operating modes from among three operating modes. A computing mode enables the memory to feed one or a plurality of read paths and enables computing circuits 212 to perform the one or a plurality of computing operations. A programming mode enables the memory to program resistive elements (not illustrated in FIG. 2) as a result of one or a plurality of computing operations, by computing circuits 212. A read mode allows the reading of the values programmed in the resistive elements comprised in memory 200.

Similarly, non-volatile memory 200 comprises other computing circuits 212, each coupled to an assembly of read paths in array 203′. These computing circuits 212 are, further, configured to generate values based on the currents at the output of the read path assembly, and to store these values in other storage elements (not illustrated in FIG. 2) comprised in area 202.

Each array 203 and 203′ comprises memory cells representing neurons of a plurality of layers of the neural network. In particular, each array 203 and 203′ comprises neurons of layers of same parity (odd/even for example). In other words, if the array 203 comprises the neurons of the input layer, for example layer 102, that is, the first layer, of neural network 100, it also comprises the neurons of the third layer, for example layer 106, etc. of neural network 100. Array 203 then comprises the second layer of the network, for example layer 104, and any other layer of even parity, if present. In another example, the neurons of the input layer are comprised in array 203′.

As an example, the neural network implemented by memory 200 is a network of relatively small size, comprising, for example, some ten layers, and for example comprising a total of at least 3 layers and of at most 10 layers.

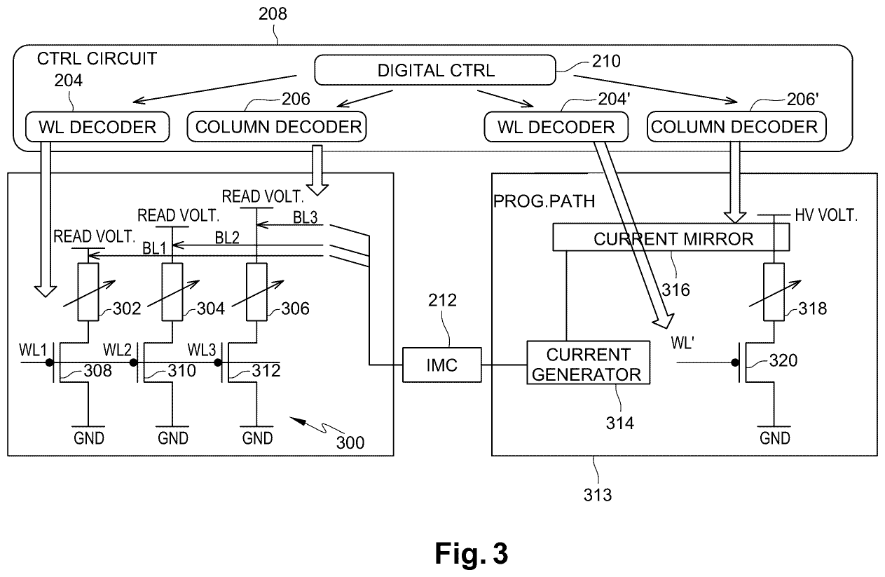

FIG. 3 illustrates a portion of non-volatile memory 200. In particular, FIG. 3 illustrates in further detail an assembly of read paths 300, comprised in array 203 and coupled to a computing circuit 212.

As an example, the assembly of read paths 300 comprises resistive elements 302, 304, and 306 of different resistances encoding weights of three neurons of a layer of the neural network. Each resistive element 302, 304, and 306 is respectively coupled by its electrodes to the source, or to the drain, of a transistor 308, 310, and 312 and to a bit line BL1, BL2, and BL3 to which is applied a read voltage (READ VOLT.). Resistive elements 302, 304, and 306 are, for example, respectively powered by bit lines BL1, BL2, and BL3, via the read voltage. Transistors 308, 310, and 312 respectively each have their gate coupled to a word line WL1, WL2, and WL3. Transistors 308, 310, and 312 are further coupled to the ground (GND) by their drain or their source. As an example, word lines WL1, WL2, and WL3 are distinct from one another. In another example, at least two resistive elements 302, 304, or 306 are coupled to a same word line. Control circuit 208 is, for example, configured to control, via digital circuit 210, the power supply of word lines WL1, WL2, and WL3. As an example, to control the power supply of the word lines, control circuit 208 places memory 200 in a computing mode.

Control circuit 208 is further configured, via digital circuit 210 and decoder 206, to supply the current at the output of each resistive element 302, 304, and 306 to one of computing circuits 212. Computing circuit 212 is, for example, configured to generate a current according to the currents at the output of elements 302, 304, and 306. As an example, the current generated by circuit 212 is a function of a sum of the currents at the output of elements 302, 304, and 306. As an example, computing circuit 212 further comprises a current amplifier configured to amplify the sum of the currents at the output of elements 302, 304, and 306. As an example, computing circuit 212 is further configured to apply compensation and/or threshold and/or offset and/or scaling effects, based on the currents at the output of elements 302, 304, and 306.

Computing circuit 212 is, for example, configured to supply the generated current to a programming circuit 313 (PROG. PATH). The programming circuit is, for example, comprised in area 202′.

As an example, programming circuit 313 comprises a current generator 314 (CURRENT GENERATOR). For example, a reference current value of current generator 314 is equal to, or a function of, the current supplied by computing circuit 212.

Programming circuit 313 further comprises, for example, a current mirror 316 (CURRENT MIRROR). As an example, current mirror 316 is coupled to current generator 314 and is configured to duplicate the current at the output of current generator 314.

In other embodiments, circuit 314 is omitted, for example if current mirror 316 is configured to apply a gain between the current supplied by computing circuit 212 and the current supplied to storage element 318.

Current mirror 316 is further coupled to another resistive element 318 and is configured to program this other resistive element 318 to a resistance value according to the current generated by computing circuit 212. For example, current generator 314 is configured to generate a programming current based on the current supplied by computing circuit 212. As an example, resistive element 318 is an element reprogrammable a plurality of times, and programming circuit 313 is configured to reprogram resistive element 318 from a current resistance value to the new resistance value based on the programming current.

Resistive element 318 is coupled by one of its electrodes to a reference voltage (HV VOLT.) and, by the other one of its electrodes, to the source, or to the drain, of a transistor 320. As an example, the reference voltage is applied to resistive element 318 only when control circuit 208 is in a programming state. Transistor 320 is, for example, coupled to ground by its drain, or its source, and its gate is, for example, coupled to a word line WL′. Word line WL′ is, for example, controlled by decoder 204′. Column decoder 206′ is, for example, configured to select the right column to be connected to current mirror 316. Column decoder 206′ is further configured to select the path coupling the cells.

The value to which resistive element 318 is programmed corresponds, for example, to an input value for the next layer of the neural network. As an example, in relation with FIG. 1, resistive elements 302, 304, and 306 program, respectively, the weights of neurons 108, 110, and 112. Bit lines BL1, BL2, and BL3 then respectively supply a current I1, I2, and I3, which is a function of the states of transistors 308, 310, and 312 and of resistive elements 302, 304, and 306. The assembly of read paths 300 then corresponds to the combination of neurons 108, 110, and 112 coupled to the neuron 116 of layer 104. Computing circuit 212 then is, for example, configured to perform the layer operation between layers 102 and 104. As an example, the layer operation corresponds to the sum of the weight-input value products for neurons 108, 110, and 112. The current generated by the computing circuit encodes input value IN′1+IN′2+IN′3. Resistive element 318 is thus configured to temporarily store the input value of the neuron 116 of layer 104. In another example, resistive elements 302, 304, and 306 encode, respectively the weights of neurons 116, 118, and 120 and computing circuit 212 is configured to generate a value corresponding to value IN″1+IN″2+IN″3. As an example, computing circuit 212 is a node coupling the bit lines of each read path. In other cases, computing circuit 212 integrates other functions which modify the sum of the currents at the output of the assembly of read paths 300. Resistive element 318 is then configured to store the input value of the neuron 122 of layer 106.

Memory 200 thus comprises a plurality of assemblies of read paths, similar to assembly 300, although the number of resistive elements differs from one path assembly to another. Each path assembly is, for example, coupled to a computing circuit 212. Each circuit 212 is configured to supply a current used for the programming of a value, corresponding to an input value for one, or a plurality of, neurons of the next layer, in a resistive element similar to element 318.

The value programmed in element 318 is delivered, in the form of a current generated via current mirror 316 and current generator 314 to the array 203′ of FIG. 2, under control of decoders 204′ and by activating one or a plurality of word lines of array 203′.

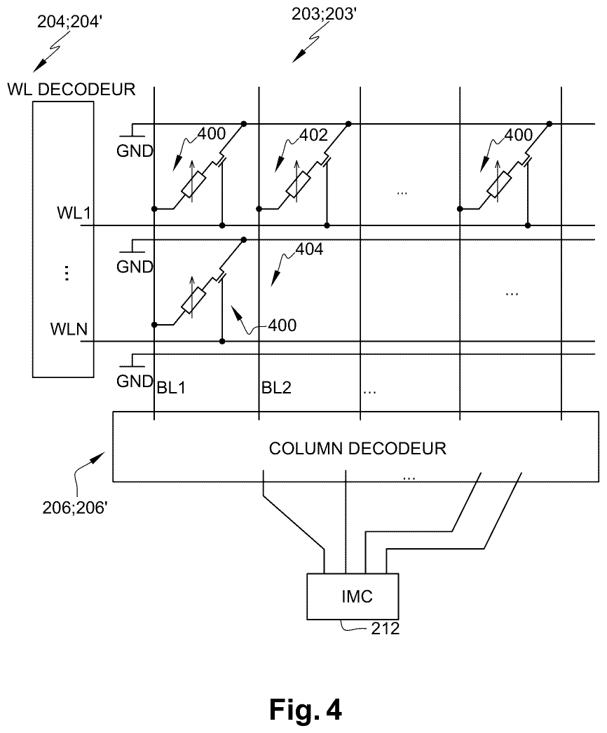

FIG. 4 is a diagram illustrating a plurality of neurons directly implemented in the non-volatile memory. In particular, FIG. 4 illustrates an example of the structure of arrays 203 and 203′.

Each of arrays 203 and 203′ comprises a plurality of memory cells 400 addressable in rows and columns. All the cells of a same row of array 203 or 203′ are, for example, coupled to a same word lines (WL1, . . . , WLN), N being an integer equal to the number of word lines, controlled by decoder 204 or 204′. Similarly, all the cells of a same column of array 203 or 203′ are coupled to a same bit line (BL1, BL2, etc.) controlled by decoder 206 or 206′. Decoders 206 or 206′ are themselves coupled to one, or a plurality of, computing circuits 212.

Memory cells 400 each comprise a resistive element, similar to the resistive elements 302, 304, and 306, described in relation with FIG. 3. The resistive element of each cell 400 is coupled by its electrodes to a bit line and to the source, or to the drain, of a transistor, similar to the transistors 308, 310, and 312 described in relation with FIG. 3. Each transistor is further coupled to ground by its drain or its source and is activated via a gate by the activation of one of the word lines.

Thus, when control circuit 208 controls, for example, the activation of word lines WL1 and WL2 and the power supply of bit line BL2, memory cells 402 and 404, located in first and second rows of the second column of array 203 or 203′ are powered. Cells 402 and 404 then form, for example, an assembly of read paths. In particular, memory cells 402 and 404 are, for example, supplied simultaneously. In other words, memory cells 402 and 404 are each supplied, at the same time, with an input current (the input current applied to cell 402 being, for example, different from the input current applied to cell 404). As an example, in relation with FIG. 1, cells 402 and 404 form the assembly comprising neurons 116 and 118 and delivering values IN″2 and IN″3 to the neuron 122 of layer 106.

Those skilled in the art will be capable of organizing the memory cells of arrays 203 and 203′ so that the activation of the word and bits lines effectively powers the desired memory cells. Indeed, for example, to power the cell on the first row and first column and the cell on the second row, second column, word lines WL1 and WL2, as well as bit lines BL1 and BL2, will be activated. Accordingly, the cells on the first row, second column, and on the second row, first column, will also be powered and contribute to the current supplied to computing circuit 212.

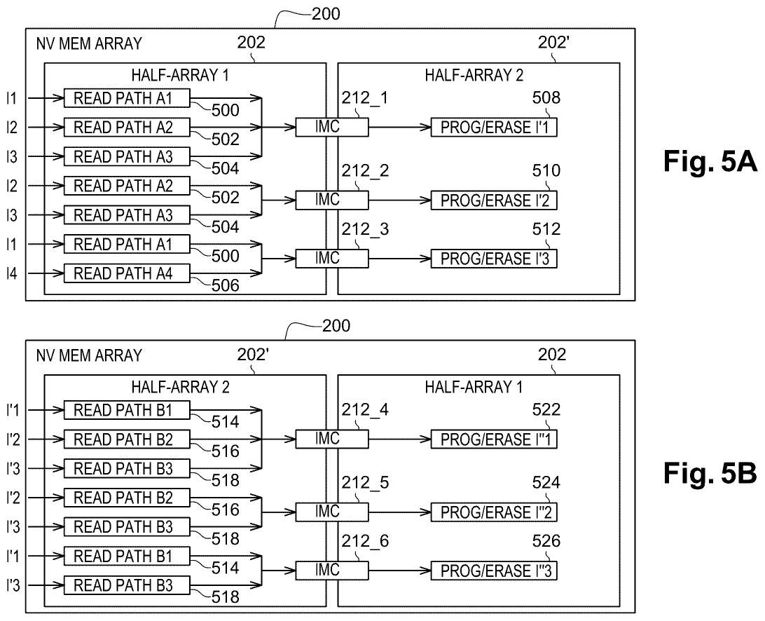

FIG. 5A illustrates computing operations performed between layers 102 and 104 of neural network 100. In particular, FIG. 5A illustrates the implementation, by non-volatile memory 200, of the operations between layers 102 and 104.

A control signal I1, corresponding to input value IN1 is supplied, via one of the word lines, for example WL1, to a memory cell 500 implementing neuron 108 (READ PATH A1). Control signal I1 is, for example, configured to control the gate of a transistor on one or a plurality of word lines. As an example, control signal I1 is based on a voltage value. In another example, the control signal is a control signal of PWM (“Pulse Width Modulation”) type based on a duty cycle. The resistive element of cell 500 has been programmed upstream to a value encoding weight A1. Similarly, signals I2, I3, and I4 are respectively supplied, via word lines, for example word line WL2, and word line WL3 and WL4 (not illustrated), to memory cells 502, 504, and 506 implementing neurons 110 (READ PATH A2), 112 (READ PATH A3), and 114 (READ PATH A4). The resistive elements of cells 502, 504, and 506 have been, respectively, programmed upstream to values encoding weights A2, A3, and A4.

The outputs of memory cells 500, 502, and 504 are, for example, supplied to a computing circuit 212_1. Computing circuit 212_1 is then configured to generate an input value, based on the outputs of cells 500, 502, and 504, for the memory cell implementing neuron 116 and comprised in array 203′. The generated value, for example encoding a signal I′1, is then programmed in a resistive element 508 (PROG/ERASE I′1) similar to resistive element 318. Signal I′1 is thus read and reused as an input of word decoder 204.

Similarly, the outputs of memory cells 502 and 504, and respectively of cells 500 and 506 are, for example, supplied to a computing circuit 212_2, and 212_3. Computing circuit 212_2, respectively circuit 212_3, is then configured to generate an input value, based on the outputs of cells 502 and 504, respectively of cells 500 and 506, for the memory cell implementing neuron 118, respectively 120, and comprised in array 203′. The generated value, for example encoding a signal I′2, respectively a signal I′3, is then programmed in a resistive element 510 (PROG/ERASE I′2), respectively 512 (PROG/ERASE I′3). Signal I′2, respectively signal I′3, is thus read and reused as an input of word decoder 204.

Control circuit 208 is, for example, configured to, first, control the power supply of the assembly of read paths formed by cells 500, 502, and 504 and coupled to computing circuit 212_1. Once the outputs of cells 500, 502, and 504 have been supplied to computing circuit 212_1, control circuit 208 controls, for example in parallel, the power supply of the assembly of the paths formed by cells 502 and 504 and coupled to computing circuit 212_2 and of the assembly of the paths formed by cells 514 and 518 and coupled to computing circuit 212_3. Indeed, the parallel power supply of the two path assemblies is possible since these two assemblies of read paths comprise no memory cell in common.

FIG. 5B illustrates computing operations performed between layers 104 and 106 of neural network 100. In particular, FIG. 5B illustrates the implementation, by non-volatile memory 200, of the operations between layers 104 and 106, for example as a result of the programming of resistive elements 508, 510, and 512.

Signal I′1 is supplied, via one of the bit lines of area 202′ to a memory cell 514 (READ PATH B1) implementing neuron 116. The resistive element of cell 514 has been programmed, upstream, to a value encoding weight B1. Similarly, signals I′2 and I′3 are respectively supplied, via word lines of area 202′, to memory cells 516 (READ PATH B2) and 518 (READ PATH B3) implementing neurons 118 and 120. Resistive elements of cells 516 and 518 have been, respectively, programmed upstream to values encoding weights B2 and B3.

The outputs of memory cells 514, 516, and 518 are, for example, supplied to a computing circuit 212_4. Computing circuit 212_4 is then configured to generate an input value, based on the outputs of cells 514, 516, and 518, for the memory cell implementing neuron 122 and comprised in array 203. The generated value, for example corresponding to a signal I″1, is then programmed in a resistive element 522 (PROG/ERASE I″1) similar to resistive element 318. As an example, the programming of the generated value is performed as a result of the suppression of a value already stored in element 522. Signal I″1 is thus read and reused as an input of word decoder 204.

Similarly, the outputs of memory cells 516 and 518, and respectively of cells 514 and 518, are for example supplied to a computing circuit 212_5, and 212_6. Computing circuit 212_5, respectively circuit 212_6, is then configured to generate an input value, based on the outputs of cells 516 and 518, respectively of cells 514 and 518, for the memory cell implementing neuron 124, respectively 126, and comprised in array 203. The generated value, for example encoding a signal I″2, respectively a signal I″3, is then programmed in a resistive element 524 (PROG/ERASE I″2), respectively 526 (PROG/ERASE I″3). Signal I″2, respectively signal I″3, is thus read and reused as an input of word decoder 204.

Control circuit 208 is, for example, configured to first control the power supply of the assembly of paths formed by cells 514, 516, and 518 and coupled to computing circuit 212_4. Control circuit 208 is then configured to control the power supply of the assembly of paths formed by cells 516 and 518 and coupled to computing circuit 212_5, then the power supply of the assembly of paths formed by cells 514 and 518 and coupled to computing circuit 212_6. Each of the assemblies having at least one memory cell in common with one of the other assemblies, the power supply is performed assembly after assembly.

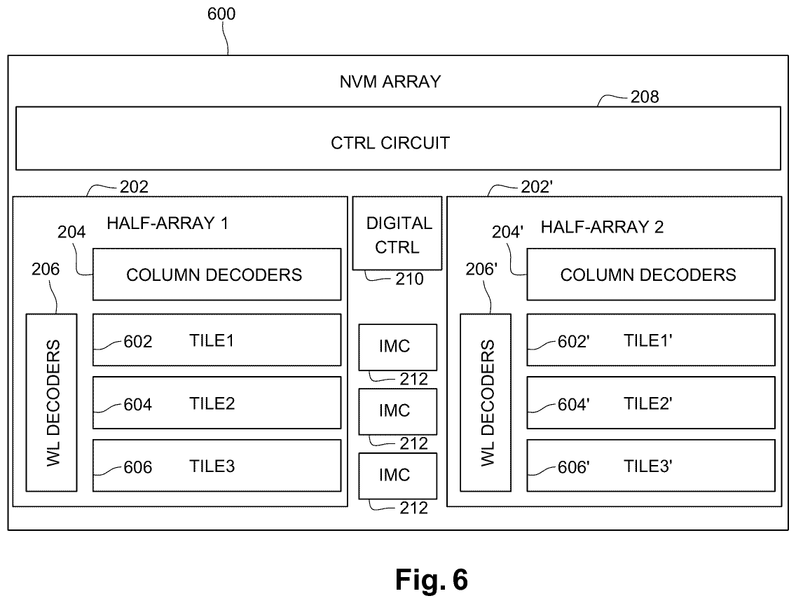

FIG. 6 is a block diagram illustrating a non-volatile memory 600. In particular, volatile memory 600 is similar to non-volatile memory 200 except that array 203 is replaced with, or comprises, sub-arrays 602 (TILE 1), 604 (TILE 2), and 606 (TILE 3). Similarly, array 203′ is replaced with, or comprises, sub-arrays 602′ (TILE 1′), 604′ (TILE 2′), and 606′ (TILE 3′). Although three sub-arrays are illustrated in FIG. 6, a number greater, or lower, than three sub-arrays may replace, or be comprised in, arrays 203 and 203′.

As an example, each sub-array comprises the memory cells of an assembly of read paths. In another example, each sub-array comprises the memory cells of a plurality of assemblies of read paths having no memory cell in common. Thus, as an example, memory cell 500 is, for example, duplicated into sub-array 602 and into sub-array 606. Generally, each memory cell appearing in at least two assemblies of read paths is duplicated into sub-arrays.

The implementation in sub-arrays and the duplication of the memory cells common to a plurality of assemblies of read paths allows the powering, and the delivery of the outputs of each assembly of paths to the associated computing circuit, in parallel.

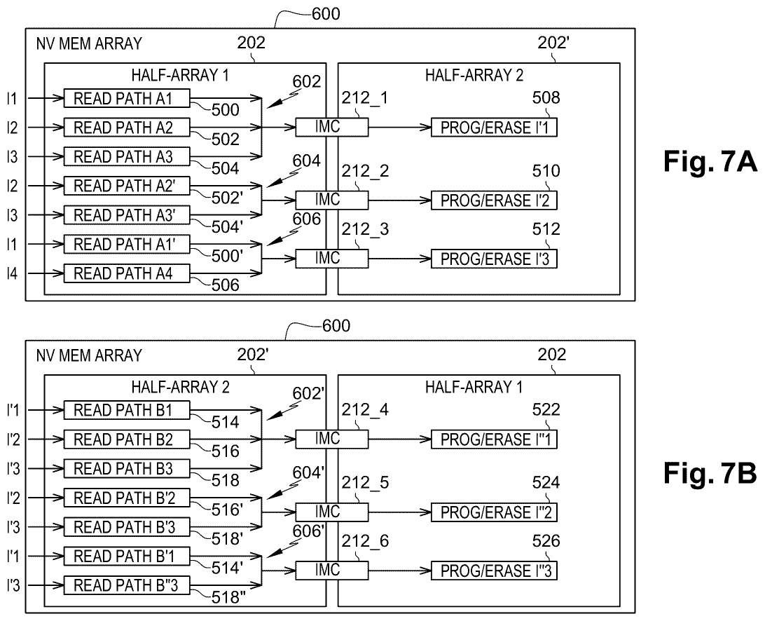

FIG. 7A illustrates an example of the computing operations performed between the layers 102 and 104 of neural network 100. In particular, FIG. 7A illustrates the implementation, by non-volatile memory 600, of the operations between layers 102 and 104.

As an example, memory cell 500 is, for example, comprised in sub-array 602, and is duplicated in a cell 500′ comprised in sub-array 606. Similarly, the cells 502 and 504 comprised in sub-array 602 are duplicated into cells 502′ and 504′ comprised in sub-array 604. Memory cell 506 being comprised in a single assembly of paths, it is, for example, not duplicated and is only implemented in sub-array 606.

The power supply of the assemblies of paths and the delivery of the outputs, to computing circuits 212_1, 212_2, and 212_3 is then performed in parallel.

FIG. 7B illustrates an example of the computing performed between the layers 104 and 106 of neural network 100. In particular, FIG. 7B illustrates the implementation, by non-volatile memory 600, of the operations between layers 104 and 106, for example as a result of the programming of resistive elements 508, 510, and 512.

As an example, memory cell 514 is comprised in sub-array 602′, and is duplicated in a cell 514′ comprised in sub-array 606′. Similarly, the cell 516 comprised in sub-array 602′ is duplicated into cells 516′ comprised in sub-array 604′. Memory cell 518 being in common in the three assemblies of paths illustrated in relation with FIG. 5B, it is duplicated into a cell 518′ comprised in sub-array 604′ and into a cell 518″, comprised in sub-array 606′.

The power supply of the assemblies of paths and the delivery of the outputs to computing circuits 212_4, 212_5, and 212_6 is then performed in parallel.

An advantage of the described embodiments is that all the computing operations performed by the neural network are performed within the non-volatile memory. Thus, there is no latency time due to the data transfer between a memory and a processor.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove. In particular, as to the arrangement of the different memory cells, and in particular the programming of the resistive elements, is within the abilities of those skilled in the art.

1. A non-volatile memory, comprising:
a first memory area comprising a first plurality of storage elements configured to store weight values associated with a first plurality of neurons of a neural network;
a second memory area comprising a second plurality of storage elements;
a control circuit, configured to apply one or more first input values to a plurality of first read paths, each first read path comprising one storage element among the first plurality of storage elements and configured to generate a read current base on at least one of the one or more first input values;
a first computing circuit configured to add read currents generated by the first read paths to generate a first output current; and
a programming circuit configured to convert the first output current into a first programming current, and to use said first programming current to program a first storage element of the second plurality of storage elements.

2. The non-volatile memory according to claim 1:
wherein the control circuit is further configured to apply, to a plurality of second read paths, one or more second input values generated by reading the first storage element of the second plurality of storage elements, each second read path comprising one storage element among the second plurality of storage elements and configured to generate a read current; and
further comprising a second computing circuit configured to add read currents generated by the second read paths to generate a second output current;
wherein the programming circuit is configured to convert the second output current into a second programming current, and to use said second programming current to program another storage element of the first memory area.

3. The non-volatile memory according to claim 2:
wherein the control circuit is further configured to apply, to a plurality of third read paths, one or more third input values generated by reading the other storage element of the first memory area, each third read path comprising one storage element among the first plurality of storage elements and configured to generate a read current; and
wherein the first computing circuit is further configured to add currents generated by the third read paths to generate a third output current; and
wherein the programming circuit is further configured to convert the third output current into a third programming current, and to reprogram the first storage element of the second plurality of storage elements by using said third programming current.

4. The non-volatile memory according to claim 3, wherein the storage elements comprised in the first read paths define weights associated with an input layer of the neural network and wherein the storage elements comprised in the third read paths define weights associated with another layer of the neural network.

5. The non-volatile memory according to claim 4, wherein the another layer is an output layer.

6. The non-volatile memory according to claim 1, wherein the weight values stored by the first plurality of storage elements define weights of neurons belonging to layers of one parity of the neural network and the weights stored by the second plurality of storage elements define weights of neurons belonging to layers of another parity of the neural network.

7. The non-volatile memory according to claim 6, wherein said one parity is odd parity and said another parity is even parity.

8. The non-volatile memory according to claim 1, wherein each storage element, among the first and the second plurality of storage elements, belongs to a memory cell, each memory cell being coupled to the control circuit via a word line and bit line, the control circuit being configured to activate or deactivate word lines and bit lines.

9. The non-volatile memory according to claim 1, wherein the first computing circuit is configured to generate the first output value, based on the currents supplied by the memory cells comprised in a read path among the first read paths.

10. The non-volatile memory according to claim 1, wherein the first computing circuit is further configured to apply compensation effects, based on the currents supplied by the memory cells comprised in a read path among the first read paths.

11. The non-volatile memory according to claim 1, wherein the first computing circuit is further configured to apply threshold effects, based on the currents supplied by the memory cells comprised in a read path among the first read paths.

12. The non-volatile memory according to claim 1, wherein the first computing circuit is further configured to apply offset effects, based on the currents supplied by the memory cells comprised in a read path among the first read paths.

13. The non-volatile memory according to claim 1, wherein the first computing circuit is further configured to apply scaling effects, based on the currents supplied by the memory cells comprised in a read path among the first read paths.

14. The non-volatile memory according to claim 1, wherein the storage elements and the other storage elements are programmable resistive elements.

15. The non-volatile memory according to claim 1, further comprising a third computing circuit configured to generate another output value, based on read currents supplied by one or more memory cells comprised in a read path among the first read paths and on the one or more first input values.

16. The non-volatile memory according to claim 15, wherein the first and the third computing circuits are configured to generate the output values based on one or more cells in common in the plurality of first read paths. the common cells being duplicated in at least two parts in the first area.

17. The non-volatile memory according to claim 1. wherein the one or more first input values are applied simultaneously to the first read paths.

18. A method, comprising:
applying one or more first input values to a plurality of first read paths, each first read path comprising one among storage elements of a first plurality of storage elements of a first area of a non-volatile memory, the first plurality of storage elements being configured to store weight values associated with a first plurality of neurons of a neural network;
adding currents supplied by the first read paths to generate a first output current;
converting the first output current into a first programming current; and
programming a first storage element of a second plurality of storage elements of a second area of the non-volatile memory using said first programming current.

19. The method according to claim 18, further comprising:
applying one or more second input values generated by reading the first one of the second plurality of storage elements to a plurality of second read paths, each second read path comprising one among the storage elements of the second plurality of storage elements;
adding the currents supplied by the second read paths to generate a second output current;
converting the second output current into a second programming current; and
programming another storage element of the first area of the non-volatile memory by using said second programming current.

20. The method according to claim 18, where applying comprised applying the one or more first input values simultaneously to the first read paths.
